(19) United States
(12) Patent Application Publication
(10) Pub. No.: US 2016/0115623 A1
(43) Pub. Date: Apr. 28, 2016

(54) WAFER CARRIER AND EPITAXIAL GROWTH DEVICE USING SAME

(71) Applicant: IBIDEN CO., LTD., Ogaki-shi, Gifu (JP)

(72) Inventor: Toshiki ITO, OOGAKI-SHI, GIFU (JP)

(21) Appl. No.: 14/895,850

(22) PCT Filed: May 14, 2014
(86) PCT No.: PCT/JP2014/062800

§ 371 Date: Dec. 3, 2015

(30) Foreign Application Priority Data
Jun. 6, 2013 (JP) 2013-120207

(51) Int. Cl. C30B 25/12; C30B 25/10; C23C 16/458; C23C 16/46; H01L 21/687; H01L 21/67

(52) U.S. Cl. CPC C30B 25/12; H01L 21/68757; H01L 21/68764; H01L 21/67103; C23C 16/458; C23C 16/46; C30B 25/10

(57) ABSTRACT

Provided is a wafer carrier with which it is unlikely that particles will be generated from a connection hole that is a connection section for connecting with a spindle, and even if particles are generated, the particles will be unlikely to spread and can be easily removed. Also provided is an epitaxial growth device using the wafer carrier. The wafer carrier comprises the following: an upper surface having at least one cavity for holding a wafer; a lower surface having in the center thereof a connection hole into which the upper end of a rotation spindle is removably inserted; and an outer circumferential part for linking the upper surface and the lower surface. The connection hole has a through hole and is formed by a tapered wall surface that increases in size from the upper surface side towards the lower surface side.

### TECHNICAL FIELD

The present invention relates to wafer carriers for growing an epitaxial film on a substrate such as a wafer, and to an epitaxial growth device employing the wafer carriers.

### BACKGROUND ART

In the semiconductor industry, the epitaxial growth method is known as a technique for obtaining a single-crystal wafer of satisfactory quality. The gas-phase epitaxial growth used in the semiconductor industry is a technique in which a single-crystal wafer is placed on a wafer carrier within a CVD apparatus and a source gas is supplied thereto to deposit one or more components of the vapor phase on the surface of the single-crystal wafer.

Patent document 1 describes an epitaxial growth device (reactor) which is for vapor-depositing an epitaxial layer on a wafer and which is capable of a reduction in reactor cycle, a cost reduction and life prolongation in component parts, and highly precise temperature control. In the epitaxial growth device of patent document 1, the wafer carrier is transported between a loading position (L) and a deposition position (D). In the deposition position, the wafer carrier is detachably mounted on an upper end of a rotatable spindle without necessitating an intermediate susceptor. The reactor of patent document 1 is capable of processing a single wafer or a plurality of wafers at the same time.

Specifically, the following is stated therein.

The insertion of the upper end of the spindle into the recess of the wafer carrier creates a friction fit between the spindle wall and the recess wall that allows the rotation of the wafer carrier by the spindle without separate holding means. As a result, during the deposition, the spindle is rotated to rotate the wafer carrier and the wafers placed in the cavities. Retaining the wafer carrier on the spindle only by friction allows the minimization of the mechanical inertia of the wafer carrier-spindle assembly and, as a result, the strain on the spindle decreases. If the spindle is suddenly stopped and force of inertia exerted upon the wafer carrier exceeds the force of friction between the upper end of the spindle, the wafer carrier rotates independently from the spindle, reducing the strain on the spindle.

### BACKGROUND ART DOCUMENT

### Patent Document

Patent Document 1: JP-T-2004-525056

### SUMMARY OF THE INVENTION

### Problems that the Invention is to Solve

However, in the epitaxial growth device described therein, the spindle has been connected to the wafer carrier by a friction fit. Because of this, the junction between the spindle and the wafer carrier is not reliable and sliding occurs between the spindle and the wafer carrier especially when the rotation is started or stopped. This wear results in the generation of particles.

Furthermore, the patent document 1 indicates that the wafer carrier of the epitaxial growth device described therein is made, for example, from graphite or molybdenum. However, these materials have the following problems. In graphite, hexagonal network planes of carbon atoms have been formed along the a-axis direction by covalent bonding, and the hexagonal network planes have been stacked along the c-axis direction by van der Waals forces to form a crystal structure. Graphite hence is likely to peel along the c-axis direction, and is a material which is likely to wear. The worn graphite gives off particles, which are likely to remain in the recess (connecting hole). In addition, the graphite particles generated fall off and are likely to contaminate the inside of the apparatus. Molybdenum is a metal having a density of 10.28 g/cm³ and a melting point of 2,896 K. Since the density thereof is at least 5 times the density of graphite, a higher load is imposed on the spindle and the wafer carrier has an increased angular moment. Consequently, particle generation due to friction is likely to occur.

In view of the problems described above, an object of the invention is to provide wafer carriers in which particles are less likely to be generated from the connecting hole that is a connecting part for connection to the spindle, and in which even if particles have generated, the particles are less likely to diffuse and can be easily removed, and to provide an epitaxial growth device employing the wafer carriers.

### Means for Solving the Problems

A wafer carrier according to the present invention for overcoming the problems may be configured as described in the following modes.

(1) A wafer carrier including: a base made of graphite and having: an upper surface having one or more cavities for holding one or more wafers; a lower surface having, at the center thereof, a connecting hole for detachably inserting an upper end of a rotating spindle thereinto; and an outer periphery that connects the upper surface to the lower surface; and a ceramic coating film that covers at least the upper surface, the lower surface, and the outer periphery of the base, wherein the connecting hole is a through hole having a tapered wall surface widening from a side of the upper-surface toward a side of the lower-surface.

According to the wafer carrier of the mode (1), since the connecting hole is defined by a tapered wall surface which becomes larger from the upper-surface side toward the lower-surface side, the inside of the connecting hole is less likely to include a corner where particles are likely to adhere and, even if particles have generated in the connecting hole, the particles can be easily removed.

(2) A wafer carrier including: a base made of graphite and having: an upper surface having one or more cavities for holding one or more wafers; a lower surface having, at the center thereof, a connecting hole for detachably inserting an upper end of a rotating spindle thereinto; and an outer periphery that connects the upper surface to the lower surface; and a ceramic coating film that covers at least the upper surface, the lower surface, and the outer periphery of the base, wherein the connecting hole has: a tapered wall surface widening from a side of the upper-surface side toward a side of the lower-surface; and a bottom surface having a boundary portion at which the bottom surface is connected with the wall surface and a central portion having deeper depth than the boundary portion.

According to the wafer carrier of the mode (2), since the connecting hole is defined by both a tapered wall surface which becomes larger from the upper-surface side toward the lower-surface side and a bottom surface which is deeper at a central portion thereof than at the boundary between the bottom surface and the wall surface, the inside of the connecting hole is less likely to include a corner where particles are likely to adhere and, even if particles have generated in the connecting hole, the particles can be easily removed.

The following modes are also acceptable for the wafer carrier according to the present invention.

(3) The bottom surface may further has a tapered surface extending from the boundary portion.

In a case where the bottom surface has a tapered surface extending from the boundary between the bottom surface and the wall surface, the corner formed between the wall surface and the bottom surface can be more obtuse. Because of this, particle adhesion to the corner portion can be made less likely to occur.

(4) The bottom surface may be configured as a dome-shaped surface extending from the boundary portion.

In a case where the bottom surface is a dome-shaped surface extending from the boundary between the bottom surface and the wall surface, the corner formed between the wall surface and the bottom surface can be more obtuse. Because of this, particle adhesion to the corner portion can be made less likely to occur.

(5) The tapered wall surface may be coated with the ceramic coating film.

In a case where the wall surface has been covered with the ceramic coating film, carbon particle generation due to friction with the rotating spindle can be made less likely to occur.

(6) The ceramic coating film may be of silicon carbide.

In a case where the ceramic coating film is silicon carbide, wear from friction can be reduced since this coating film is a hard ceramic coating film, and particle generation can be further diminished. In addition, since silicon carbide has electrical conductivity, this ceramic coating film is less likely to be charged and can be kept in such a state that particles generated by friction are less likely to adhere thereto and are easily removed.

(7) The base made of graphite may be monolithically configured.

Since the base made of graphite has a low resistivity comparable to those of metals, this integrally formed base accelerates charge movement to dissipate the charges outside. Thus, particle adhesion can be prevented, and the removal of particles which have adhered can be facilitated. In addition, in cases when the ceramic coating film which covers the surfaces of the wafer carrier is a material having electrical conductivity, such as silicon carbide, the effect is enhanced.

(8) The outer periphery may have a flange having a retaining surface facing downward, and the ceramic coating film may have a thickness that is thinner at the retaining surface of the outer periphery than at the upper surface of the base.

It may be important that the upper surface of the wafer carrier should be thickly covered with the ceramic coating film in order to prevent the graphite base from being corroded by source gases, but the retaining surface is less required to be thus covered because the retaining surface is not the region to which source gases are supplied. Consequently, by thinly forming the ceramic coating film having a higher resistivity than the graphite base on the retaining surface of the flange, charges can be dissipated through the conveying jig when the wafer carrier is conveyed therewith. Hence, by forming the ceramic coating film more thinly on the retaining surface than on the upper surface, the effect of preventing static buildup can be produced.

The epitaxial growth device according to the present invention for overcoming the problems may be configured as described in the following mode.

(9) An epitaxial growth device including the wafer carrier according to any one of modes (1) to (8); a rotating spindle having an opening at an upper end; a heater that heats the wafer carrier; and a source-gas supplying unit that is arranged at a position above the wafer carrier, wherein the opening of the rotating spindle is connected to a gas suctioning unit that suctions gases.

According to the epitaxial growth device of the mode (9), since the opening of the rotating spindle has been connected to a gas suctioning unit, the particles which have accumulated in the space formed between the rotating spindle and the wafer carrier can be removed before diffusing in the epitaxial growth device.

### Advantages of the Invention

According to the wafer carrier of the modes of the present invention, since the connecting hole is defined by a tapered wall surface which becomes larger from the upper-surface side toward the lower-surface side, the inside of the connecting hole is less likely to include a corner where particles are likely to adhere and, even if particles have generated in the connecting hole, the particles can be easily removed.

According to the wafer carrier of the modes of the invention, since the connecting hole is defined by both a tapered wall surface which becomes larger from the upper-surface side toward the lower-surface side and a bottom surface which is deeper at a central portion thereof than at the boundary between the bottom surface and the wall surface, the inside of the connecting hole is less likely to include a corner where particles are likely to adhere and, even if particles have generated in the connecting hole, the particles can be easily removed.

Furthermore, the wafer carrier of the modes of the present invention have a feature wherein since the opening of the rotating spindle has been connected to a gas suctioning unit, the particles which have accumulated in the space formed between the rotating spindle and the wafer carrier can be removed from the inside of the epitaxial growth device before diffusing in the apparatus.

### BRIEF DESCRIPTION OF THE DRAWINGS

FIG. 1 is a sectional view of one example of epitaxial growth device.

FIG. 2 is a perspective view of one example of the wafer carriers.

FIG. 3 shows plan views showing the cavities in the upper surface of the wafer carrier of FIG. 2, wherein FIG. 3 (a) illustrates the cavities of first embodiment and second embodiment, and FIGS. 3 (b) to 3 (d) illustrate modifications thereof.

FIG. 4 shows cross-sectional views of the outer peripheries of wafer carriers, wherein FIG. 4 (a) illustrates the wafer carrier of first embodiment, and FIGS. 4 (b) to 4 (d) illustrate modifications thereof.

FIG. 5 shows cross-sectional views regarding the connecting holes of wafer carriers, wherein FIG. 5 (a) illustrates the wafer carrier of first embodiment according to the present invention, and FIGS. 5 (b) and 5 (c) illustrate modifications thereof.

FIG. 6 is a cross-sectional view illustrating a modification of the wafer carrier of first embodiment in which a pin has been inserted into the connecting hole.

FIG. 7 shows cross-sectional views regarding the connecting holes of wafer carriers, wherein FIG. 7 (a) illustrates the wafer carrier of second embodiment, and FIGS. 7 (b) and 7 (c) illustrate modifications thereof.

FIG. 8 shows cross-sectional views regarding the ceramic coating of the wafer carrier of second embodiment, wherein FIG. 8 (a) illustrates the wafer carrier having a ceramic coating film on the upper surface, lower surface, and outer periphery, and FIG. 8 (b) illustrates the wafer carrier having a ceramic coating film further on the tapered wall surface of the connecting hole.

FIG. 9 illustrates a modification of the wafer carrier of second embodiment, which is a wafer carrier wherein the center of the upper surface protrudes so that the bottom surface of the connecting hole is above those areas of the wafer-carrier upper surface on which wafers are placed.

FIG. 10 shows modifications of the wafer carrier of second embodiment, wherein FIG. 10 (a) illustrates a wafer carrier wherein the opening of the connecting hole projects and lies below the lower surface of the wafer carrier, and FIG. 10 (b) illustrates a wafer carrier wherein the opening of the connecting hole is recessed and lies above the lower surface of the wafer carrier.

FIG. 11 is a sectional view of an epitaxial growth device according to the present invention.

### MODES FOR CARRYING OUT THE INVENTION

Embodiments of the invention are explained below.

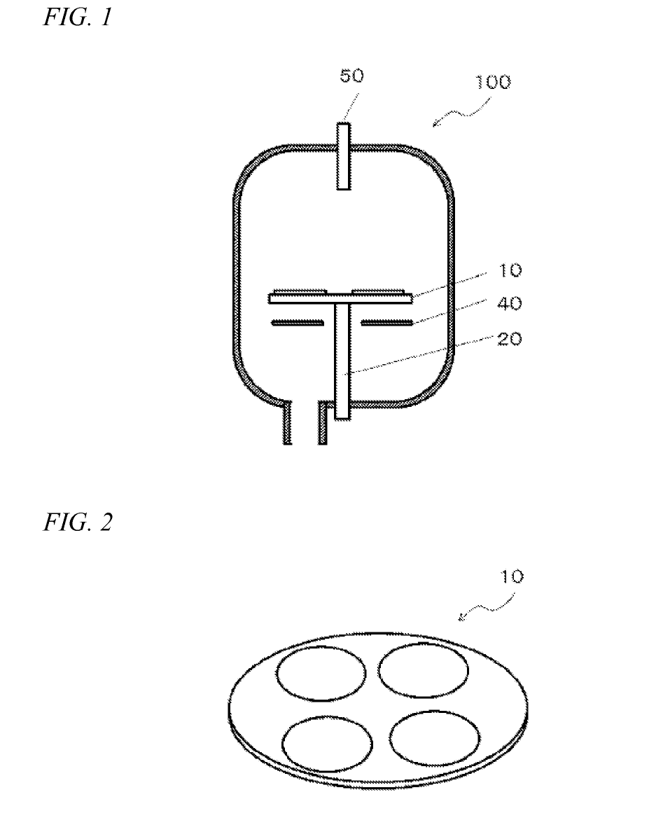

A wafer carrier is used in epitaxial growth device. FIG. 1 shows an example of an epitaxial growth device. The epitaxial growth device 100 is equipped inside with a wafer carrier 10 for placing wafers thereon, and further equipped with a heater 40 under the wafer carrier 10. The wafer carrier 10 has been disposed on the upper end of a rotating spindle 20. A source gas is introduced into the epitaxial growth device to thereby form a coating film on the wafers. FIG. 2 is a perspective view of the wafer carrier used in the epitaxial growth device of FIG. 1.

In first embodiment, an explanation is given for a wafer carrier in which the connecting hole 5 is a through hole. In second embodiment, an explanation is given for a wafer carrier in which the connecting hole 5 is a bottomed hole. Unless otherwise indicated, the explanations can be applied to both the first embodiment and the second embodiment.

The first embodiment is a wafer carrier related to claim 1 of the present disclosure, and the second embodiment is a wafer carrier related to claim 2 of the present disclosure. There are modifications of first embodiment and of second embodiment, and the modifications will be suitably explained.

In this description, the upper and lower direction for a wafer carrier coincides with the upper and lower direction for the wafer carrier mounted in an epitaxial growth device. Namely, the side where cavities for placing wafers therein have been formed is the upper direction, while the side where the connecting hole for attaching a rotating spindle thereto has been formed is the lower direction.

The wafer carrier according to first embodiment of the present invention is a wafer carrier which has an upper surface 6 having one or more cavities 6a for holding one or more wafers, a lower surface 7 having, at the center thereof, a connecting hole 5 for detachably inserting the upper end of a rotating spindle 20 thereinto, and an outer periphery 4 that connects the upper surface 6 to the lower surface 7, and which includes a base 1 made of graphite and a ceramic coating film 2 that covers at least the upper surface, the lower surface, and the outer periphery, wherein the connecting hole 5 is a through hole defined by a tapered wall surface 5a which becomes larger from the upper-surface side toward the lower-surface side.

The wafer carrier 10 of this embodiment is directly attached to the rotating spindle 20.

The wafer carrier 10 of this embodiment has, at the center of the lower surface thereof, a connecting hole 5 for connection with the rotating spindle 20 so that this wafer carrier can be conveyed from outside the epitaxial growth device 100 with an auto-loader or the like and be easily attached and detached.

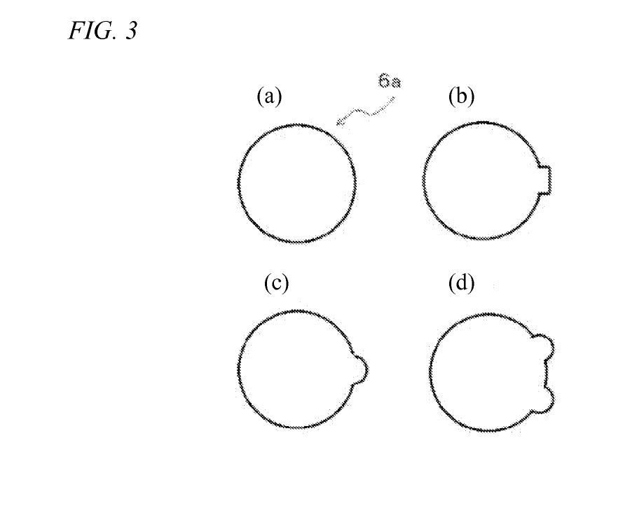

The wafer carrier of this embodiment has, in the upper surface 6, cavities 6a for placing wafers therein. The cavities are not particularly limited in the shape or number thereof. Examples of the shape of the cavities include circular cavities (see FIG. 3 (a)) according to the shape of the wafers, and further include modifications thereof which facilitate insertion of a spatula from the periphery during wafer takeout, such as a cavity composed of a large circle and a small square in combination (see FIG. 3 (b)), a cavity composed of a large circle and one small circle in combination (see FIG. 3 (c)), and a cavity composed of a large circle and two small circles in combination (see FIG. 3 (d)). The shape of the cavities is not particularly limited.

The wafer carrier of this embodiment is configured of an upper surface 6, a lower surface 7, and an outer periphery 4 which connects the upper surface to the lower surface. It is preferable that the wafer carrier 10 of this embodiment should be one which, except the cavities for placing wafers therein, is a rotationally asymmetric disk with respect to the center axis perpendicular to the upper surface and lower surface. In other words, the wafer carrier of this embodiment has the shape of a disk which is rotationally asymmetric with respect to the center axis perpendicular to the upper surface and lower surface and in which cavities for placing wafers therein have been formed on the upper-surface side.

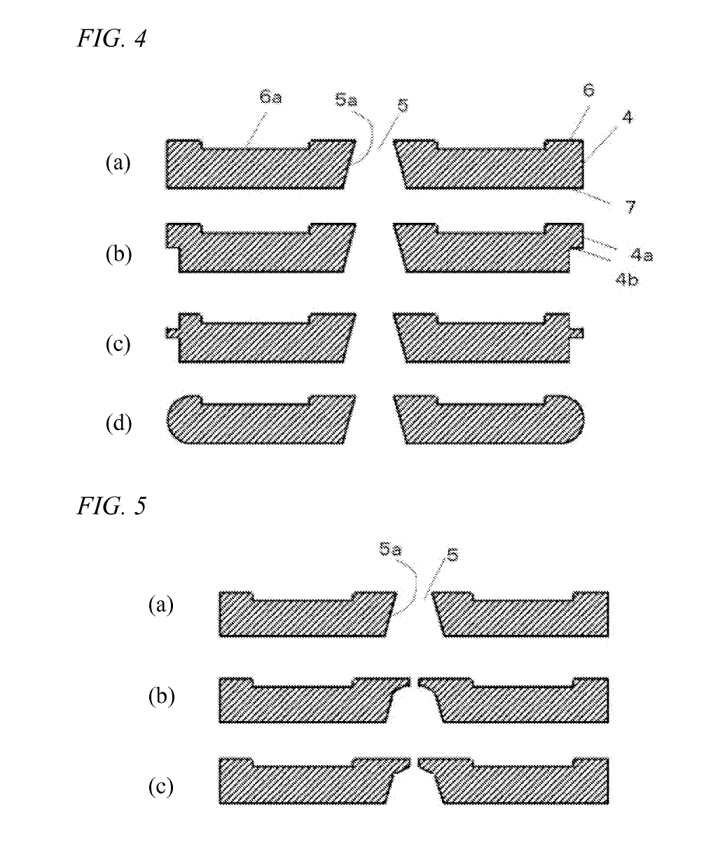

The shape of the outer periphery 4 of the wafer carrier 10 of this embodiment is not particularly limited. Examples of the shape of the outer periphery include a cylindrical side surface which perpendicularly connects the upper surface to the lower surface (see FIG. 4 (a)), a curved surface which, in a cross-sectional view including the center axis, gives circular arcs that smoothly connect the upper surface to the lower surface (see FIG. 4 (d)), a shape in which a flange having a retaining surface facing downward has been formed (see FIG. 4 (b)), and a shape having a collar (see FIG. 4 (c)). Preferred of these is the shape in which a flange having a retaining surface facing downward has been formed.

In cases when a flange having a retaining surface facing downward has been formed in the wafer carrier of this embodiment, this wafer carrier can be easily conveyed in and out from an epitaxial growth device using an auto-loader that is equipped at the end with a conveying jig in which the space between the holders for conveyance is larger than the diameter of the lower surface but smaller than the diameter of the flange.

The wafer carrier 10 of this embodiment has, at the center of the lower surface, a connecting hole 5 for detachably inserting the upper end of a rotating spindle 20. In other words, a connecting hole 5 has been formed in the center-axis portion of the disk forming the wafer carrier.

The connecting hole 5 of the wafer carrier of this embodiment has a tapered wall surface 5a which becomes larger from the upper-surface side toward the lower-surface side. Since the connecting hole 5 of the wafer carrier of this embodiment is a hole having a tapered wall surface, a connection by moderate friction connection can be established by connecting thereto a rotating spindle 20 having a corresponding tapered projection. Thus, rotating force can be transmitted from the rotating spindle 20 to the wafer carrier 10 without requiring any separate holding means, and the wafer carrier 10 can be easily attached and detached.

The wafer carrier 10 of this embodiment includes a base 1 made of graphite and a ceramic coating film 2 which covers the upper surface, lower surface, and outer periphery. Since the base 1 of the wafer carrier 10 of this embodiment is made of graphite, this wafer carrier can be more lightweight and have a smaller angular moment than heat-resistant metals such as molybdenum. Consequently, the load and torque imposed on the connecting hole 5 can be reduced. As a result, the force of friction applied to the wall surface 5a of the connecting hole 5 can be reduced, and particle generation can be diminished.

Since the wafer carrier 10 of this embodiment has a ceramic coating film 2 which covers the upper surface, lower surface, and outer periphery, the graphite can be inhibited from being corroded by source gases even in the case of using ammonia, hydrogen, organometals, etc. in epitaxial growth.

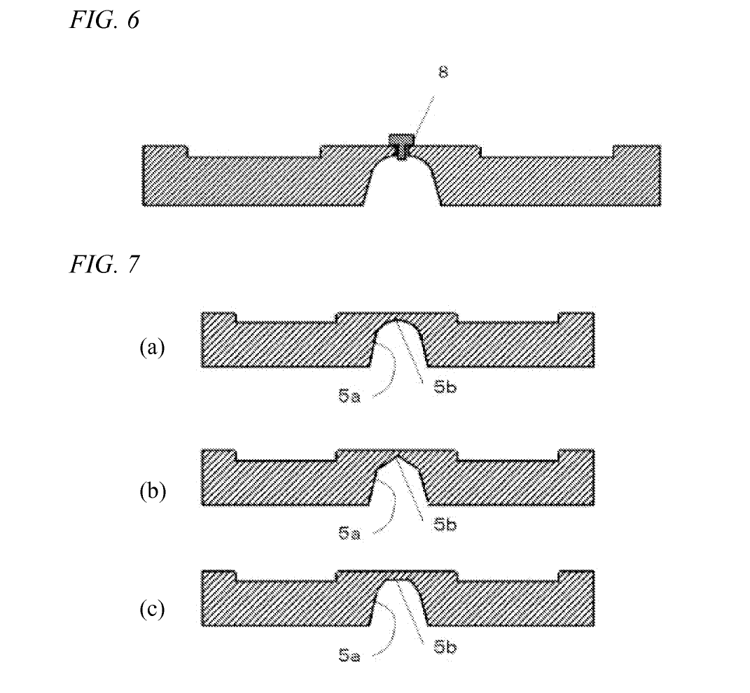

The connecting hole 5 of the wafer carrier 10 of first embodiment is a through hole. Particles which have been generated by friction can be easily removed, for example, by blowing air from above so that the air passes through the through hole. Methods for particle removal are not limited to air blowing, and the particles can be easily removed by wiping with a brush, cloth, etc. since the connecting hole 5 is a through hole. The connecting hole of the wafer carrier of first embodiment is defined by a single tapered surface so that the connecting hole does not include a corner where particles are likely to accumulate. (See FIG. 5 (a).) Examples of modifications thereof include a curved surface in which the slope changes continuously (see FIG. 5 (b)) and a tapered surface having a small slope angle (see FIG. 5 (c)). In each case, the connecting hole is a through hole. Since the connecting hole of the wafer carrier of the invention is a through hole, the connecting hole is open on the upper-surface side. This wafer carrier may be used with a pin 8 inserted into the connecting hole so that the source gas does not penetrate into the connecting hole through the opening (see FIG. 6). Although the material of the pin 8 is not particularly limited, it is preferable that the material thereof should be the same as that of the wafer carrier 10. In cases when the material of the pin 8 is the same as that of the wafer carrier 10, the pin 8 shows the same thermal expansion behavior. Consequently, this pin 8 is less likely to be difficult to draw out after use, and a gap is less likely to be formed to cause vibration, etc. during use. The pin 8 can be cleaned each time after use and reused. Alternatively, the pin 8 may be replaced with fresh one each time after use.

It is preferable that the tapered wall surface 5a of the wafer carrier 10 of this embodiment be covered with a ceramic coating film 2. FIG. 8 (a) shows a wafer carrier in which the tapered wall surface of the connecting hole has not been covered with a ceramic coating film and the graphite is exposed. FIG. 8 (b) shows a wafer carrier in which the tapered wall surface of the connecting hole has been covered with a ceramic coating film. Although the wafer carriers of FIG. 8 do not have a through hole, the explanation is applicable also to this embodiment, which has a through hole.

In the graphite used as the base of the wafer carrier 10 of this embodiment, hexagonal network planes of carbon atoms have been formed along the a-axis direction by covalent bonding and the hexagonal network planes have been stacked along the c-axis direction by van der Waals forces to form a crystal structure. Graphite hence is likely to peel along the c-axis direction, and is a soft material.

Since the tapered wall surface 5a of the wafer carrier 10 of this embodiment has been covered with the ceramic coating film 2, the ceramic coating film can inhibit the graphite from wearing.

Since the wafer carrier 10 of this embodiment employs lightweight graphite as the base and the tapered wall surface 5a has been covered with the ceramic coating film 2, the wear due to the force of friction occurring between the rotating spindle and the wafer carrier can be reduced and the generation of particles by friction can be diminished.

Examples of the ceramic coating film 2 of the wafer carrier of this embodiment include coating films of pyrolytic carbon and coating films of silicon carbide. Methods for forming these ceramic coating films are not particularly limited. For example, the coating films can be formed by a CVD method. Since silicon carbide coating films, among those, are hard and have electrical conductivity, use thereof as the ceramic coating film covering the tapered wall surface has the following features. Since the coating film is hard, this coating film is less likely to be worn by the force of friction with the rotating spindle. Furthermore, since the surface of the graphite, which has a low resistivity, has been covered with the silicon carbide coating film, which has electrical conductivity, this wafer carrier is less likely to be charged and can be kept in such a state that particles generated by friction are less likely to adhere thereto and are easily removed.

It is preferable that the silicon carbide coating film which covers the tapered wall surface of the wafer carrier of this embodiment should be β-form silicon carbide. A coating film of β-form silicon carbide can be obtained by film deposition by a CVD method at, for example, 1,100-1,400° C. Since β-form silicon carbide has a hardness of 3,000-4,000 Hv, use of this silicon carbide is suitable. The silicon carbide coating film which covers the tapered wall surface of the wafer carrier has a surface roughness (Ra) of desirably 0.1-5 μm. In cases when the surface roughness (Ra) thereof is 0.1 μm or higher, sufficient force of friction is obtained and, hence, the rotating force of the rotating spindle can be efficiently transmitted to the wafer carrier. In cases when the surface roughness (Ra) thereof is 5 μm or less, this silicon carbide coating film is sufficiently low in the ability to abrade the rotating spindle and, hence, particle generation can be diminished. Compared to the silicon carbide obtained by the common sintering method, the silicon carbide obtained by a CVD method has a high purity because of the nonuse of a sintering aid. Since the β-form silicon carbide coating film obtained by a CVD method has electrical conductivity, this coating film not only prevents the wafer carrier from being charged and thereby prevents particle adhesion thereto, but also can facilitate the removal of particles which have adhered. Most of the particles which have generated due to friction during the period when the rotating spindle inserted into the wafer carrier is rotating accumulate in the space formed between the rotating spindle and the wafer carrier. Incidentally, the resistivity of the silicon carbide coating film is desirably 0.01-1 Ωcm. So long as the resistivity thereof is 1 Ωcm or less, the charges of the charged wafer carrier surface can be easily dissipated, and the particles generated can be made less likely to adhere. The resistivity of the silicon carbide can be easily regulated by doping with an impurity.

Since the tapered wall surface of the connecting hole of the wafer carrier 10 of this embodiment has electrical conductivity, the charges can be dissipated via the rotating spindle 20 and the particles generated can readily fall off. In the case where the rotating spindle 20 is a conductive object, e.g., a metal, charges are readily dissipated. This configuration hence is more effective.

It is preferable that the graphite base of the wafer carrier 10 of this embodiment should have been monolithically formed. Since the graphite base has a low resistivity comparable to those of metals, the monolithic configuration not only accelerates the movement of charges to facilitate charge dissipation to the outside but also prevents particle adhesion and facilitates the removal of particles which have adhered. In the case where the ceramic coating film 2 which covers the surfaces of the wafer carrier 10 is a material having electrical conductivity, such as silicon carbide, the effects can be maintained further.

It is preferable that in the wafer carrier 10 of this embodiment, a flange having a retaining surface facing downward should be formed on the outer periphery 4 and that the ceramic coating film should be formed so that the thickness thereof on the retaining surface is smaller than the thickness thereof on the upper surface. It is important that the upper surface of the wafer carrier 10 should be thickly covered with the ceramic coating film 2 in order to prevent the graphite base from being corroded by source gases, but the retaining surface 4b facing downward is less required to satisfy the protection of the graphite base since source gases are less likely to reach the retaining surface 4b. Because of this, by thinly covering the retaining surface of the flange even with a ceramic coating film having a higher resistivity than the graphite base, charges can be dissipated via the conductive jig when the wafer carrier is conveyed therewith. Consequently, by forming the ceramic coating film more thinly on the retaining surface than on the upper surface, such an effect can be produced.

Next, the epitaxial growth device of this embodiment is explained.

In the epitaxial growth device 100 of this embodiment, particles generated by friction between the wafer carrier 10 and the rotating spindle 20 can be collected by using, as the rotating spindle 20, one which has an opening at the upper end thereof. In cases when a rotating spindle having an opening at the upper end is used, the particles generated can be easily removed by cleaning the inside of the opening. The rotating spindle 20 having an opening at the upper end is not particularly limited. The rotating spindle may be a rod-shaped rotating spindle which has an opening formed in the upper end only and in which the opening is shallow, or may be a pipe-shaped rotating spindle having a deep opening.

The rotating spindle 20 of the epitaxial growth device of the invention is further equipped with a gas suctioning unit 30 which removes gases from the opening at the upper end. The gas suctioning unit removes the particles which have accumulated in the space formed between the rotating spindle and the wafer carrier before diffusing in the epitaxial growth device.

Next, the wafer carrier of second embodiment is explained.

The wafer carrier of second embodiment according to the present invention is a wafer carrier which has an upper surface 6 having one or more cavities 6a for holding one or more wafers, a lower surface 7 having, at the center thereof, a connecting hole 5 for detachably inserting the upper end of a rotating spindle thereinto, and an outer periphery 4 that connects the upper surface to the lower surface, and which includes a base made of graphite and a ceramic coating film that covers at least the upper surface, the lower surface, and the outer periphery, wherein the connecting hole 5 is defined by both a tapered wall surface which becomes larger from the upper-surface side toward the lower-surface side and a bottom surface which is deeper at a central portion thereof than at the boundary between the bottom surface and the wall surface.

The wafer carrier 10 of this embodiment is directly attached to the rotating spindle 20.

The wafer carrier 10 of this embodiment has, at the center of the lower surface thereof, a connecting hole 5 for connection with the rotating spindle 20 so that this wafer carrier can be conveyed from outside the epitaxial growth device 100 with an auto-loader or the like and be easily attached and detached.

The wafer carrier 10 of this embodiment has, in the upper surface, cavities 6a for placing wafers therein. The cavities are not particularly limited in the shape or number thereof. Examples of the shape of the cavities include circular cavities (see FIG. 3 (a)) according to the shape of the wafers, and further include modifications thereof which facilitate insertion of a spatula from the periphery during wafer takeout, such as a cavity composed of a large circle and a small square in combination (see FIG. 3 (b)), a cavity composed of a large circle and one small circle in combination (see FIG. 3 (c)), and a cavity composed of a large circle and two small circles in combination (see FIG. 3 (d)). The shape of the cavities is not particularly limited.

The wafer carrier 10 of this embodiment is configured of an upper surface 6, a lower surface 7, and an outer periphery 4 which connects the upper surface to the lower surface. It is preferable that the wafer carrier 10 of the invention should be one which, except the cavities for placing wafers therein, is a rotationally asymmetric disk with respect to the center axis perpendicular to the upper surface and lower surface. In other words, the wafer carrier of this embodiment has the shape of a disk which is rotationally asymmetric with respect to the center axis perpendicular to the upper surface and lower surface and in which cavities for placing wafers therein have been formed on the upper-surface side.

The shape of the outer periphery 4 of the wafer carrier 10 of this embodiment is not particularly limited. Examples of the shape of the outer periphery 4 include a cylindrical side surface which perpendicularly connects the upper surface to the lower surface (see FIG. 4 (a)), a curved surface which, in a cross-sectional view including the center axis, gives circular arcs that smoothly connect the upper surface to the lower surface (see FIG. 4 (d)), a shape in which a flange having a retaining surface facing downward has been formed (see FIG. 4 (b)), and a shape having a collar (see FIG. 4 (c)). Preferred of these is the shape in which a flange having a retaining surface facing downward has been formed. Although the wafer carriers shown in FIG. 4 each have a through hole as the connecting hole, the shapes described above are applicable also to second embodiment, in which the connecting hole is not a through hole.

In a case where a flange having a retaining surface facing downward has been formed in the wafer carrier of this embodiment, this wafer carrier can be easily conveyed in and out from an epitaxial growth device using an auto-loader that is equipped at the end with a conveying jig in which the space between the holders for conveyance is larger than the diameter of the lower surface but smaller than the diameter of the flange.

The wafer carrier 10 of this embodiment has, at the center of the lower surface, a connecting hole 5 for detachably inserting the upper end of a rotating spindle 20. In other words, a connecting hole has been formed in the center-axis portion of the disk forming the wafer carrier.

The connecting hole of the wafer carrier of this embodiment is defined by both a tapered wall surface which becomes larger from the upper-surface side toward the lower-surface side and a bottom surface which is deeper at a central portion thereof than at the boundary between the bottom surface and the wall surface. Since the connecting hole 5 of the wafer carrier 10 of this embodiment is a hole having a tapered wall surface 5a, a connection of moderate friction can be established by connecting thereto a rotating spindle 20 having a tapered projection. Thus, rotating force can be transmitted from the rotating spindle to the wafer carrier without requiring any separate holding means, and the wafer carrier can be easily attached and detached.

The wafer carrier 10 of this embodiment includes a base 1 made of graphite and a ceramic coating film 2 which covers the upper surface 6, lower surface 7, and outer periphery 4. Since the base of the wafer carrier 10 of this embodiment is made of graphite, this wafer carrier can be more lightweight and have a smaller angular moment than heat-resistant metals such as molybdenum. Consequently, the load and torque imposed on the connecting hole can be reduced. As a result, the force of friction applied to the wall surface of the connecting hole can be reduced, and particle generation can be diminished.

Since the wafer carrier 10 of this embodiment has a ceramic coating film 2 which covers the upper surface 6, lower surface 7, and outer periphery 4, the graphite can be inhibited from being corroded by source gases even in the case of using ammonia, hydrogen, organometals, etc. in epitaxial growth.

The bottom surface 5b of the connecting hole 5 of the wafer carrier of this embodiment is deeper at a central portion thereof than at the boundary between the bottom surface and the wall surface. The expression “the bottom surface 5b is deeper at a central portion thereof than at the boundary between the bottom surface and the wall surface 5a” means that the portion which is crossed by the center axis lies deeper than the portion connected to the tapered wall surface. It is preferable that the depth of the connecting hole 5 should become gradually larger from the tapered wall surface 5a toward the portion which is crossed by the center axis. Examples of such a shape include the case where the bottom surface has a tapered surface extending from the boundary between the bottom surface and the wall surface (see FIG. 7 (b) and FIG. 7 (c)) and the case where the bottom surface is a dome-shaped surface extending from the boundary between the bottom surface and the wall surface (see FIG. 7 (a)).

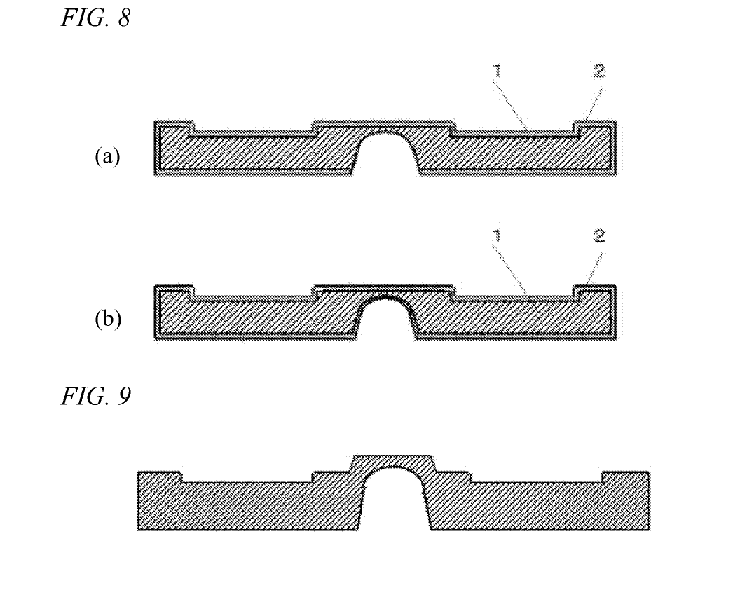

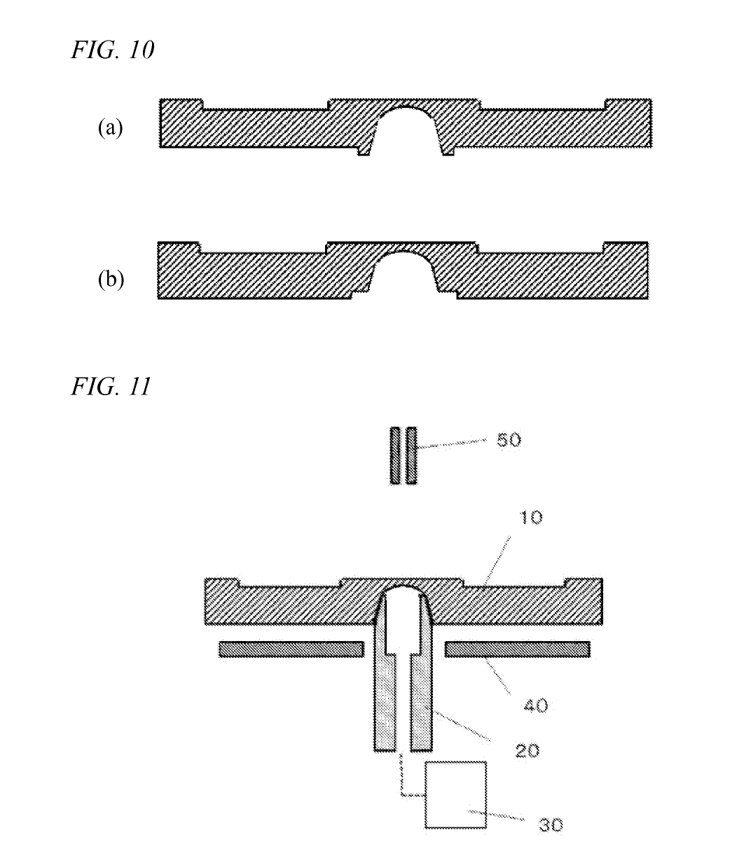

The shape of the wafer carrier 10 of this embodiment is not limited to such shapes. Examples of modifications thereof include: a wafer carrier wherein the center of the upper surface protrudes so that the bottom surface of the connecting hole lies above those areas of the wafer-carrier upper surface on which wafers are placed (see FIG. 9); a wafer carrier wherein the opening of the connecting hole projects and lies below the lower surface of the wafer carrier (see FIG. 10 (a)); and a wafer carrier wherein the opening of the connecting hole is recessed and lies above the lower surface of the wafer carrier (see FIG. 10 (a)).

In a case where the bottom surface of the connecting hole 5 of the wafer carrier 10 of this embodiment has a tapered surface extending from the boundary between the bottom surface and the wall surface 5a or is a dome-shaped surface extending from the boundary between the bottom surface and the wall surface, it is possible to eliminate the corner portion to which particles generated by friction are likely to adhere. The particles which have adhered can be easily removed, for example, by air blowing. Methods for particle removal are not limited to air blowing, and the particles can be easily removed by wiping with a brush, cloth, etc.

It is preferable that the tapered wall surface 5a of the wafer carrier 10 of this embodiment should be covered with a ceramic coating film 2. FIG. 8 (a) shows a wafer carrier in which the tapered wall surface of the connecting hole has not been covered with a ceramic coating film and the graphite is exposed. FIG. 8 (b) shows a wafer carrier in which the tapered wall surface of the connecting hole has been covered with a ceramic coating film.

In the graphite used as the base of the wafer carrier 10 of this embodiment, hexagonal network planes of carbon atoms have been formed along the a-axis direction by covalent bonding and the hexagonal network planes have been stacked along the c-axis direction by van der Waals forces to form a crystal structure. Graphite hence is a soft material and is likely to peel along the c-axis direction.

Since the tapered wall surface of the wafer carrier of this embodiment has been covered with the ceramic coating film, the ceramic coating film can inhibit the graphite from wearing.

Since the wafer carrier 10 of this embodiment employs lightweight graphite as the base and the tapered wall surface 5a has been covered with the ceramic coating film 2, the wear due to the force of friction occurring between the rotating spindle 20 and the wafer carrier 10 can be reduced and the generation of particles by friction can be diminished.

Examples of the ceramic coating film 2 of the wafer carrier 10 of this embodiment include coating films of pyrolytic carbon and coating films of silicon carbide. Methods for forming these ceramic coating films are not particularly limited. For example, the coating films can be formed by a CVD method. Since silicon carbide coating films, among those, are hard and have electrical conductivity, use thereof as the ceramic coating film covering the tapered wall surface has the following features. Since the coating film is hard, this coating film is less likely to be worn by the force of friction with the rotating spindle. Furthermore, since the surface of the graphite, which has a low resistivity, has been covered with the silicon carbide coating film, which has electrical conductivity, this wafer carrier is less likely to be charged and can be kept in such a state that particles generated by friction are less likely to adhere thereto and are easily removed.

It is preferable that the silicon carbide coating film which covers the tapered wall surface 5a of the wafer carrier 10 of this embodiment should be β-form silicon carbide. A coating film of β-form silicon carbide can be obtained by film deposition by a CVD method at, for example, 1,100-1,400° C. Since β-form silicon carbide has a hardness of 3,000-4,000 Hv, use of this silicon carbide is suitable. The silicon carbide coating film which covers the tapered wall surface of the wafer carrier has a surface roughness (Ra) of desirably 0.1-5 μm. In cases when the surface roughness (Ra) thereof is 0.1 μm or higher, sufficient force of friction is obtained and, hence, the rotating force of the rotating spindle can be efficiently transmitted to the wafer carrier. In cases when the surface roughness (Ra) thereof is 5 μm or less, this silicon carbide coating film is sufficiently low in the ability to abrade the rotating spindle and, hence, particle generation can be diminished. Compared to the silicon carbide obtained by the common sintering method, the silicon carbide obtained by a CVD method has a high purity because of the nonuse of a sintering aid. Since the β-form silicon carbide coating film obtained by a CVD method has electrical conductivity, this coating film not only prevents the wafer carrier from being charged and thereby prevents particle adhesion thereto, but also can facilitate the removal of particles which have adhered. Most of the particles which have generated due to friction during the rotation period when the rotating spindle inserted into the wafer carrier accumulates in the space formed between the rotating spindle and the wafer carrier. Incidentally, the resistivity of the silicon carbide coating film is desirably 0.01-1 Ωcm. So long as the resistivity thereof is 1 Ωcm or less, the charges of the charged wafer carrier surface can be easily dissipated, and the particles generated can be made less likely to adhere. The resistivity of the silicon carbide can be easily regulated by doping with an impurity.

Since the tapered wall surface 5a of the connecting hole 5 of the wafer carrier of this embodiment has electrical conductivity, the charges can be dissipated via the rotating spindle 20 and the particles generated can readily fall off. In the case where the rotating spindle 20 is a conductive object, e.g., a metal, charges are readily dissipated. This configuration hence is more effective.

It is preferable that the graphite base of the wafer carrier of this embodiment should be integrally formed. Since the graphite base has a low resistivity comparable to those of metals, the integral formation not only accelerates the movement of charges to facilitate charge dissipation to the outside but also prevents particle adhesion and facilitates the removal of particles which have adhered. In the case where the ceramic coating film which covers the surfaces of the wafer carrier is a material having electrical conductivity, such as silicon carbide, the effects can be maintained further.

It is preferable that in the wafer carrier 10 of this embodiment, a flange 4a having a retaining surface 4b facing downward should be formed on the outer periphery 4 and that the ceramic coating film should be formed so that the thickness thereof on the retaining surface is smaller than the thickness thereof on the upper surface. It is important that the upper surface of the wafer carrier 10 should be thickly covered with the ceramic coating film 2 in order to prevent the graphite base from being corroded by source gases, but it is less necessary to protect the retaining surface facing downward with the graphite base since source gases are less likely to reach the retaining surface. Because of this, by thinly covering the retaining surface 4b of the flange even with a ceramic coating film having a higher resistivity than the graphite base, charges can be dissipated via the conductive conveying jig when the wafer carrier is conveyed therewith. Consequently, by forming the ceramic coating film more thinly on the retaining surface than on the upper surface, such an effect can be produced.

Next, the epitaxial growth device 100 of this embodiment is explained. FIG. 11 is a sectional view of the epitaxial growth device of this embodiment.

In the epitaxial growth device 100 of this embodiment, particles generated by friction between the wafer carrier 10 and the rotating spindle 20 can be collected by using, as the rotating spindle 20, one which has an opening at the upper end thereof. In cases when a rotating spindle 20 having an opening at the upper end is used, the particles generated can be easily removed by cleaning the inside of the opening.

In the wafer carrier 10 to be used in the epitaxial growth device of this embodiment, in cases when the bottom surface of the connecting hole has a tapered surface extending from the boundary between the bottom surface and the wall surface or is a dome-shaped surface extending from the boundary between the bottom surface and the wall surface, it is possible to eliminate the corner portion to which particles generated by friction are likely to adhere. Since the wafer carrier is being rotated at a high speed by the rotating spindle, the particles generated by friction are collected by the centrifugal force at the peripheral part of the bottom part (i.e., at the boundary between the bottom surface and the wall surface). Since the connecting hole 5 has no corner portion to which particles are likely to adhere, most of the particles collected at the peripheral part fall off and are collected in the opening of the rotating spindle 20. Furthermore, in cases when the surface of the graphite, which has a low resistivity, has been covered with a silicon carbide coating film, which has electrical conductivity, the bottom surface can be less likely to be charged. Thus, the particles generated are likely to fall off into the opening of the rotating spindle 20 and can be made less likely to scatter in the epitaxial growth device 100.

The rotating spindle 20 having an opening at the upper end is not particularly limited. The rotating spindle may be a rod-shaped rotating spindle which has an opening formed in the upper end only and in which the opening is shallow, or may be a pipe-shaped rotating spindle having a deep opening.

The rotating spindle 20 of the epitaxial growth device of the invention is further equipped with a gas suctioning unit 30 which removes gases from the opening at the upper end. The gas suctioning unit removes the particles which have accumulated in the space formed between the rotating spindle and the wafer carrier before diffusing in the epitaxial growth device.

As described above, by using the wafer carrier of this embodiment and an epitaxial growth device in combination, an epitaxial growth device reduced in particle generation can be provided.

### DESCRIPTION OF THE REFERENCE NUMERALS AND SIGNS

1 Substrate
2 Ceramic coating film
4 Outer periphery
4a Flange
4b Retaining surface
5 Connecting hole
5a Wall surface
5b Bottom surface
6 Upper surface
6a Cavity
7 Lower surface
8 Pin
10 Wafer carrier
20 Rotating spindle
30 Gas suctioning unit
40 Heater
50 Source gas supplying unit
100 Epitaxial growth device

1. A wafer carrier comprising:
a base made of graphite and having:
an upper surface having one or more cavities for holding one or more wafers;
a lower surface having, at the center thereof, a connecting hole for detachably inserting an upper end of a rotating spindle thereinto; and
an outer periphery that connects the upper surface to the lower surface; and
a ceramic coating film that covers at least the upper surface, the lower surface, and the outer periphery of the base,
wherein the connecting hole is a through hole having a tapered wall surface widening from a side of the upper-surface toward a side of the lower-surface.

2. A wafer carrier comprising:
a base made of graphite and having:
an upper surface having one or more cavities for holding one or more wafers;
a lower surface having, at the center thereof, a connecting hole for detachably inserting an upper end of a rotating spindle thereinto; and
an outer periphery that connects the upper surface to the lower surface; and
a ceramic coating film that covers at least the upper surface, the lower surface, and the outer periphery of the base,
wherein the connecting hole has:
a tapered wall surface widening from a side of the upper-surface side toward a side of the lower-surface; and
a bottom surface having a boundary portion at which the bottom surface is connected with the wall surface and a central portion having deeper depth than the boundary portion.

3. The wafer carrier according to claim 2,
wherein the bottom surface further has a tapered surface extending from the boundary portion.

4. The wafer carrier according to claim 2,
wherein the bottom surface is configured as a dome-shaped surface extending from the boundary portion.

5. The wafer carrier according to claim 1,
wherein the tapered wall surface is coated with the ceramic coating film.

6. The wafer carrier according to claim 1,
wherein the ceramic coating film is made of silicon carbide.

7. The wafer carrier according to claim 1,
wherein the base made of graphite is monolithically configured.

8. The wafer carrier according to claim 1,
wherein the outer periphery has a flange having a retaining surface facing downward, and
wherein the ceramic coating film has a thickness that is thinner at the retaining surface of the outer periphery than at the upper surface of the base.

9. An epitaxial growth device comprising:
the wafer carrier according to claim 1;
a rotating spindle having an opening at an upper end;
a heater that heats the wafer carrier; and
a source-gas supplying unit that is arranged at a position above the wafer carrier,
wherein the opening of the rotating spindle is connected to a gas suctioning unit that suctions gases.

10. The wafer carrier according to claim 2,
wherein the tapered wall surface is coated with the ceramic coating film.

11. The wafer carrier according to claim 2,
wherein the ceramic coating film is made of silicon carbide.

12. The wafer carrier according to claim 2,
wherein the base made of graphite is monolithically configured.

13. The wafer carrier according to claim 2,
wherein the outer periphery has a flange having a retaining surface facing downward, and
wherein the ceramic coating film has a thickness that is thinner at the retaining surface of the outer periphery than at the upper surface of the base.

14. An epitaxial growth device comprising:
the wafer carrier according to claim 2;
a rotating spindle having an opening at an upper end;
a heater that heats the wafer carrier; and
a source-gas supplying unit that is arranged at a position above the wafer carrier,
wherein the opening of the rotating spindle is connected to a gas suctioning unit that suctions gases.
